(19) United States
(12) Patent Application Publication
(10) Pub. No.: US 2025/0234507 A1
(43) Pub. Date: Jul. 17, 2025

(54) SEMICONDUCTOR DEVICE HAVING INFORMATION STORAGE STRUCTURE

(71) Applicant: Samsung Electronics Co., Ltd., Suwon-si (KR)

(72) Inventors: Hyeonsong Cha, Suwon-si (KR); Euihyuk Kim, Suwon-si (KR); Jiyeon Chang, Suwon-si (KR); Hanyeong Yu, Suwon-si (KR)

(21) Appl. No.: 18/830,691

(22) Filed: Sep. 11, 2024

(30) Foreign Application Priority Data
Jan. 15, 2024 (KR) 10-2024-0005947

(51) Int. Cl. H10B 12/00

(52) U.S. Cl. CPC H10B 12/315; H10B 12/318

(57) ABSTRACT

A semiconductor device includes a lower structure having a conductive region, and an information storage structure electrically connected to the conductive region. The information storage structure includes a lower electrode electrically connected to the conductive region, a dielectric layer on the lower electrode, and an upper electrode on the dielectric layer. The lower electrode includes a first electrode material layer, a second electrode material layer, and a third electrode material layer. The first electrode material layer extends on at least a portion of a side surface of the third electrode material layer, and a bottom surface of the third electrode material layer. The second electrode material layer is between an upper portion of the first electrode material layer and the third electrode material layer.

### CROSS-REFERENCE TO RELATED APPLICATION(S)

This application claims benefit of priority to Korean Patent Application No. 10-2024-0005947 filed on Jan. 15, 2024 in the Korean Intellectual Property Office, the disclosure of which is incorporated herein by reference in its entirety.

### FIELD

The present inventive concept relates to a semiconductor device having an information storage structure.

### BACKGROUND

As demand for implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it may be necessary to implement patterns having a relatively fine width or fine separation distance.

### SUMMARY

According to an aspect of the present inventive concept, there is provided a semiconductor device including a lower structure having a conductive region, and an information storage structure electrically connected to the conductive region. The information storage structure may include a lower electrode electrically connected to the conductive region, a dielectric layer on the lower electrode, and an upper electrode on the dielectric layer. The lower electrode may include a first electrode material layer, a second electrode material layer, and a third electrode material layer. The first electrode material layer may extend on at least a portion of a side surface of the third electrode material layer, and on a bottom surface of the third electrode material layer. The second electrode material layer may be between an internal surface of an upper portion of the first electrode material layer and the third electrode material layer. According to another aspect of the present inventive concept, there is provided a semiconductor device including a lower structure having a conductive region, and an information storage structure electrically connected to the conductive region. The information storage structure may include a lower electrode electrically connected to the conductive region and extending away from the lower structure in a first direction, one or more support layers in contact with a side surface of the lower electrode, the one or more support layers extending in a second direction that intersects the first direction, a dielectric layer on the lower electrode and the one or more support layers, and an upper electrode on the dielectric layer. The lower electrode may include a first structure and a second structure on the first structure. The first structure may include a first lower electrode layer and a third lower electrode layer. The second structure may include a first upper electrode layer that is integral or continuous with the first lower electrode layer, a third upper electrode layer that is integral or continuous with the third lower electrode layer, and an insertion layer between the first upper electrode layer and the third upper electrode layer.

According to another aspect of the present inventive concept, there is provided a semiconductor device including a lower structure having a conductive region, and an information storage structure electrically connected to the conductive region. The information storage structure may include a lower electrode electrically connected to the conductive region and extending away from the lower structure in a first direction, one or more support layers in contact with a side surface of the lower electrode, the one or more support layers extending in a second direction that intersects the first direction, a dielectric layer on the lower electrode and the one or more support layers, and an upper electrode on the dielectric layer. The lower electrode may include a first electrode material layer having a cylindrical shape, a second electrode material layer on the first electrode material layer, and a third electrode material layer on the first electrode material layer and the second electrode material layer. The second electrode material layer may be on an internal surface within the cylindrical shape of an upper portion of the first electrode material layer. The third electrode material layer may include a lower portion, an intermediate portion, and an upper portion. The lower portion of the third electrode material layer may be surrounded by the first electrode material layer. The intermediate portion of the third electrode material layer may be surrounded by the second electrode material layer. The upper portion of the third electrode material layer may be surrounded by one of the one or more support layers.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor device according to an example embodiment;

FIG. 2 is a vertical cross-sectional view of the semiconductor device illustrated in FIG. 1, taken along lines I-I′ and II-II′;

FIG. 3 is an enlarged view of a portion of the semiconductor device illustrated in FIG. 2;

FIGS. 4, 5, and 6 are cross-sectional views of the semiconductor device illustrated in FIG. 3, taken along lines III-III, IV-IV′, and V-V′, respectively;

FIGS. 7, 8, 9, 10, and 11 are vertical cross-sectional views of semiconductor devices according to example embodiments;

FIGS. 12A and 12B are flowcharts illustrating methods of forming a semiconductor device according to an example embodiment;

FIGS. 13, 14, 15, 16, 17, 18, 19, 20, and 21 are vertical cross-sectional views of sequential processes of a method of manufacturing a semiconductor device according to an example embodiment;

FIG. 22 is a plan view of an integrated circuit device according to example embodiments; and

FIG. 23 is a vertical cross-sectional view of the integrated circuit device illustrated in FIG. 10, taken along lines X1-X1′ and Y1-Y1′.

### DETAILED DESCRIPTION OF EMBODIMENTS

Hereinafter, preferred example embodiments of the present inventive concept will be described below, with reference to the accompanying drawings. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

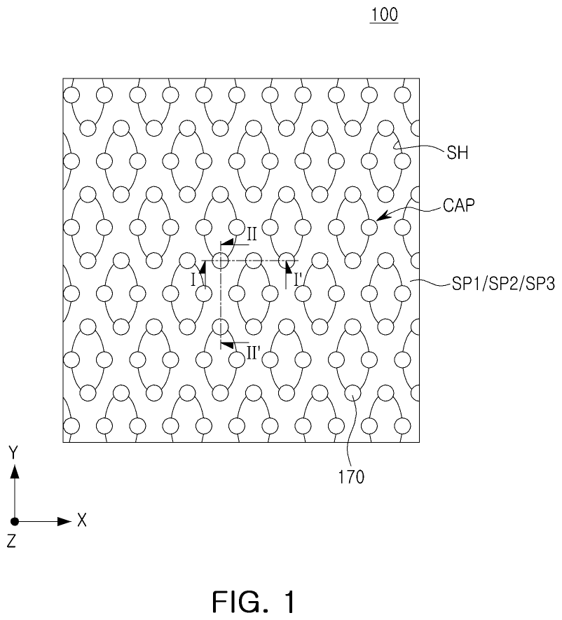

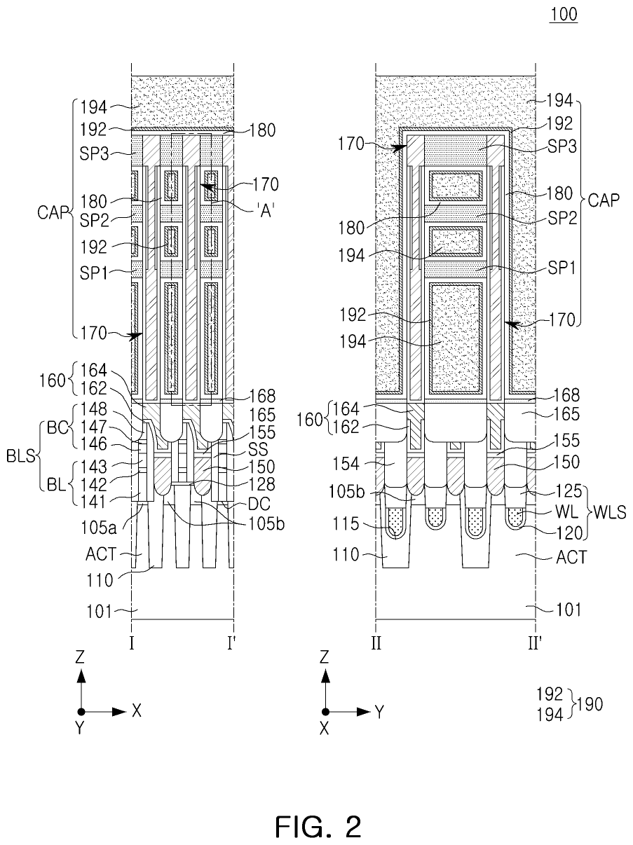

FIG. 1 is a plan view of a semiconductor device according to an example embodiment. FIG. 2 is a vertical cross-sectional view of the semiconductor device illustrated in FIG. 1, taken along lines I-I′ and II-II′.

Referring to FIGS. 1 and 2, a semiconductor device 100 may include a substrate 101 having active regions ACT, an isolation layer 110 defining the active regions ACT in the substrate 101, a word line structure WLS buried and extending in the substrate 101 to extend, the word line structure WLS including a word line WL, a bit line structure BLS extending on the substrate 101 to intersect the word line structure WLS, the bit line structure BLS including a bit line BL, and an information storage structure CAP on the bit line structure BLS. The information storage structure CAP may store information, and may be, for example, a capacitor structure of a DRAM. The semiconductor device 100 may further include a lower conductive pattern 150 on the active region ACT, an upper conductive pattern 160 on the lower conductive pattern 150, and an insulating pattern 165 passing through the upper conductive pattern 160.

The semiconductor device 100 may include, for example, a cell array of a dynamic random access memory (DRAM). For example, the bit line BL may be connected to a first impurity region 105a of the active region ACT, and a second impurity region 105b of the active region ACT may be electrically connected to the information storage structure CAP on the upper conductive pattern 160 through the lower and upper conductive patterns 150 and 160.

The information storage structure CAP may be a capacitor capable of storing information in a memory such as a DRAM. The information storage structure CAP may be electrically connected to conductive regions 150 and 160, for example, the conductive regions 150 and 160 on a lower structure including the lower and upper conductive patterns 150 and 160. Here, the lower structure may include the substrate 101, the word line structure WLS, and the bit line structure BLS.

The information storage structure CAP may include lower electrodes 170, a dielectric layer 180 on the lower electrodes 170, and an upper electrode 190 on the dielectric layer 180. The information storage structure CAP may further include support layers SP1, SP2, and SP3.

The semiconductor device 100 may include a cell array region in which a cell array is disposed, and a peripheral circuit region in which peripheral circuits for driving memory cells, disposed in the cell array, are disposed. The peripheral circuit region may be disposed around the cell array region.

The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may be a silicon substrate, a silicon on insulator (SOI) substrate, a germanium substrate, a germanium on insulator (GOI) substrate, a silicon-germanium substrate, or a substrate including an epitaxial layer.

The active regions ACT may be defined in the substrate 101 by the isolation layer 110. The active region ACT may have a bar shape, and may have an island shape, extending in one direction, in the substrate 101. The extension direction of the active region ACT may be inclined or non-orthogonal with respect to a direction of extension of the word lines WL and the bit lines BL. The active regions ACT may be arranged to be parallel to each other, and an end of one active region ACT may be arranged to be adjacent to a central portion of another active region ACT, adjacent to the one active region ACT.

The active region ACT may have first and second impurity regions 105a and 105b having a predetermined depth from an upper surface of the substrate 101. The first and second impurity regions 105a and 105b may be spaced apart from each other. The first and second impurity regions 105a and 105b may serve as source and drain regions of a transistor formed by the word line WL. The source region and the drain region, formed by the first and second impurity regions 105a and 105b caused by doping or ion implantation of substantially the same impurities, may be interchangeably referred to depending on a circuit configuration of a finally formed transistor. The impurities may include impurities having a conductivity type opposite to that of the substrate 101. In example embodiments, in the source region and the drain region, depths of the first and second impurity regions 105a and 105b may be different from each other.

The isolation layer 110 may be formed using a shallow trench isolation (STI) process. The isolation layer 110 may electrically isolate the active regions ACT from each other while surrounding the active regions ACT. The isolation layer 110 may be formed of an insulating material, for example, silicon oxide, silicon nitride, or a combination thereof. The isolation layer 110 may have a plurality of regions having a lower end depth varying depending on a width of a trench in which the substrate 101 is etched.

The word line structures WLS may be disposed in gate trenches 115, extending in the substrate 101. Each of the word line structures WLS may include a gate dielectric layer 120, a word line WL, and a gate capping layer 125. As used herein, a “gate 120 and WL” may be referred to as a structure including the gate dielectric layer 120 and the word line WL, and the word line WL may be referred to as a “gate electrode,” and the word line structure WLS may be referred to as a “gate structure.”

The word line WL may extend in a first direction X across the active region ACT. For example, a pair of word lines WL, adjacent to each other, may cross one active region ACT. The word line WL may form a gate of a buried channel array transistor (BCAT), but the present inventive concept is not limited thereto. In example embodiments, the word lines WL may be disposed on an upper portion of the substrate 101. The word line WL, having a predetermined thickness, may be disposed on a lower portion of a gate trench 115. An upper surface of the word line WL may be positioned on a level, lower than that of the upper surface of the substrate 101. As used herein, the term “level” may be defined based on or relative to a substantially flat upper surface of the substrate 101.

The word line WL may include a conductive material, for example, at least one of polycrystalline silicon (Si), titanium (Ti), titanium nitride (TiN), tantalum (Ta), tantalum nitride (TaN), tungsten (W), tungsten nitride (WN), and aluminum (Al). As an example, the word line WL may include a lower pattern and an upper pattern formed of different materials. The lower pattern may include at least one of tungsten (W), titanium (Ti), tantalum (Ta), tungsten nitride (WN), titanium nitride (TiN), and tantalum nitride (TaN). The upper pattern may be a semiconductor pattern including polysilicon doped with a P-type or N-type impurity.

The gate dielectric layer 120 may be disposed on a bottom surface and internal side surfaces of the gate trench 115. The gate dielectric layer 120 may conformally cover an internal wall of the gate trench 115. The gate dielectric layer 120 may include at least one of silicon oxide, silicon nitride, and silicon oxynitride. The gate dielectric layer 120 may be, for example, a silicon oxide film or an insulating film having a high dielectric constant. In example embodiments, the gate dielectric layer 120 may be a layer formed by oxidizing the active region ACT or a layer formed by deposition.

The gate capping layer 125 may be disposed on an upper portion of the word line WL to fill the gate trench 115. An upper surface of the gate capping layer 125 may be positioned on a level, substantially the same as that of the upper surface of the substrate 101. The gate capping layer 125 may be formed of an insulating material, for example, silicon nitride.

The bit line structure BLS may extend in a direction, perpendicular to the word line WL, for example, a second direction Y. The bit line structure BLS may include a bit line BL, and a bit line capping pattern BC on the bit line BL.

The bit line BL may include a first conductive pattern 141, a second conductive pattern 142, and a third conductive pattern 143 that are sequentially stacked. The bit line capping pattern BC may be disposed on the third conductive pattern 143. A buffer insulating layer 128 may be disposed between the first conductive pattern 141 and the substrate 101, and a portion (hereinafter, a bit line contact pattern DC) of the first conductive pattern 141 may be in contact with the first impurity region 105a of the active region ACT. The bit line BL may be electrically connected to the first impurity region 105a through the bit line contact pattern DC. A lower surface of the bit line contact pattern DC may be positioned on a level, lower than that of the upper surface of the substrate 101, and may be positioned on a level, higher than that of the upper surface of the word line WL. In an example embodiment, the bit line contact pattern DC may be formed in the substrate 101 to be locally disposed in a bit line contact hole, exposing the first impurity region 105a.

The first conductive pattern 141 may include a semiconductor material such as polycrystalline silicon. The first conductive pattern 141 may be in direct contact with the first impurity region 105a. The second conductive pattern 142 may include a metal-semiconductor compound. The metal-semiconductor compound may be, for example, a layer obtained by silicidizing a portion of the first conductive pattern 141. For example, the metal-semiconductor compound may include cobalt silicide (CoSi), titanium silicide (TiSi), nickel silicide (NiSi), tungsten silicide (WSi), or other metal silicides. The third conductive pattern 143 may include a metal material such as titanium (Ti), tantalum (Ta), tungsten (W), and aluminum (Al). In some example embodiments, the number of conductive patterns forming the bit line BL, a type of material, and/or a stacking order may be changed in various manners.

The bit line capping pattern BC may include a first capping pattern 146, a second capping pattern 147, and a third capping pattern 148 sequentially stacked on the third conductive pattern 143. Each of the first to third capping patterns 146, 147, and 148 may include an insulating material, for example, a silicon nitride film. The first to third capping patterns 146, 147, and 148 may be formed of different materials. Even when the first to third capping patterns 146, 147, and 148 include the same material, the first to third capping patterns 146, 147, and 148 may be distinguished from each other by a difference in physical properties. A thickness of the second capping pattern 147 may be narrower than a thickness of the first capping pattern 146 and a thickness of the third capping pattern 148, respectively. In some example embodiments, the number of capping patterns and/or a type of material forming the bit line capping pattern BC may be changed in various manners.

Spacer structures SS may be disposed on opposite sidewalls of each of the bit line structures BLS to extend in a direction, for example, a Y-direction. The spacer structures SS may be disposed between the bit line structure BLS and the lower conductive pattern 150. The spacer structures SS may extend along sidewalls of the bit line BL and sidewalls of the bit line capping pattern BC. A pair of spacer structures SS, disposed on opposite sides of one bit line structure BLS, may have an asymmetrical shape with respect to the bit line structure BLS. Each of the spacer structures SS may include a plurality of spacer layers, and may further include an air spacer in some example embodiments.

The lower conductive pattern 150 may be connected to a region of the active region ACT, for example, the second impurity region 105b. The lower conductive pattern 150 may be disposed between the bit lines BL and between the word lines WL. The lower conductive pattern 150 may pass through the buffer insulating layer 128 to be connected to the second impurity region 105b of the active region ACT. The lower conductive pattern 150 may be in direct contact with the second impurity region 105b. A lower surface of the lower conductive pattern 150 may be positioned on a level, lower than that of the upper surface of the substrate 101, and may be positioned on a level, higher than that of the lower surface of the bit line contact pattern DC. The lower conductive pattern 150 may be insulated from the bit line contact pattern DC by the spacer structure SS. The lower conductive pattern 150 may be formed of a conductive material. For example, the conductive material may include at least one of polycrystalline silicon (Si), titanium (Ti), titanium nitride (TiN), tantalum (Ta), tantalum nitride (TaN), tungsten (W), tungsten nitride (WN), and aluminum (Al). In example embodiments, the lower conductive pattern 150 may include a plurality of layers.

A metal-semiconductor compound layer 155 may be disposed between the lower conductive pattern 150 and the upper conductive pattern 160. The metal-semiconductor compound layer 155 may be, for example, a layer obtained by silicidizing a portion of the lower conductive pattern 150, when the lower conductive pattern 150 includes a semiconductor material. The metal-semiconductor compound layer 155 may include, for example, cobalt silicide (CoSi), titanium silicide (TiSi), nickel silicide (NiSi), tungsten silicide (WSi), or other metal silicides. In some example embodiments, the metal-semiconductor compound layer 155 may be omitted.

The upper conductive pattern 160 may be disposed on the lower conductive pattern 150. The upper conductive pattern 160 may extend between the spacer structures SS to cover an upper surface of the metal-semiconductor compound layer 155. The upper conductive pattern 160 may include a barrier layer 162 and a conductive layer 164. The barrier layer 162 may cover a lower surface and side surfaces of the conductive layer 164. The barrier layer 162 may include a metal nitride, for example, at least one of titanium nitride (TiN), tantalum nitride (TaN), and tungsten nitride (WN). The conductive layer 164 may include a conductive material, for example, at least one of polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and tungsten nitride (WN).

Insulating patterns 165 may be disposed between upper conductive patterns 160. The insulating patterns 165 may electrically insulate the upper conductive patterns 160 from each other. The insulating patterns 165 may include an insulating material, for example, at least one of silicon oxide, silicon nitride, and silicon oxynitride.

An etch stop layer 168 may cover the insulating patterns 165 between the lower electrodes 170. The etch stop layer 168 may be in contact with lower regions of side surfaces of the lower electrodes 170. The etch stop layer 168 may be disposed below the support layers SP1, SP2, and SP3. An upper surface of the etch stop layer 168 may include a portion in direct contact with the dielectric layer 180. The etch stop layer 168 may include, for example, at least one of silicon nitride, silicon oxynitride, and silicon carbonitride.

The lower electrodes 170 may be disposed on the upper conductive patterns 160. The lower electrodes 170 may have a pillar shape. The lower electrodes 170 may be spaced apart from each other in an X-direction and a Y-direction. In an example embodiment, the lower electrodes 170 may be arranged to have a honeycomb structure. For example, as illustrated in FIG. 1, the lower electrodes 170 may be disposed at vertices of a hexagonal pattern and at the center of the hexagonal pattern, respectively.

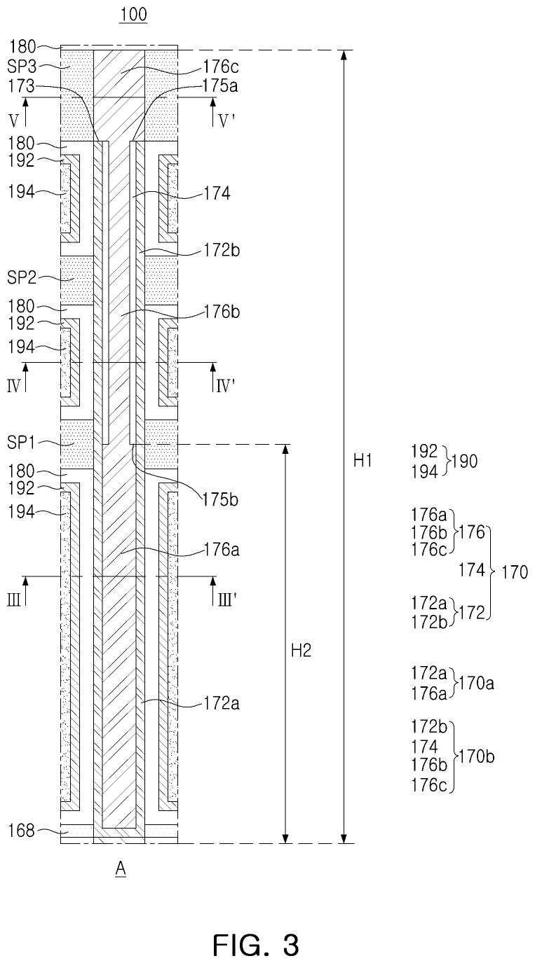

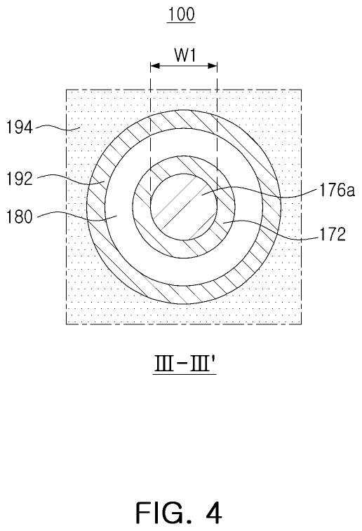

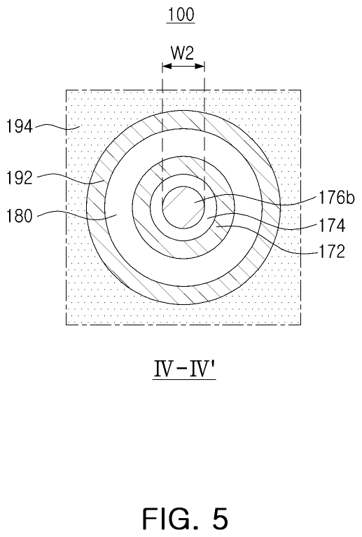

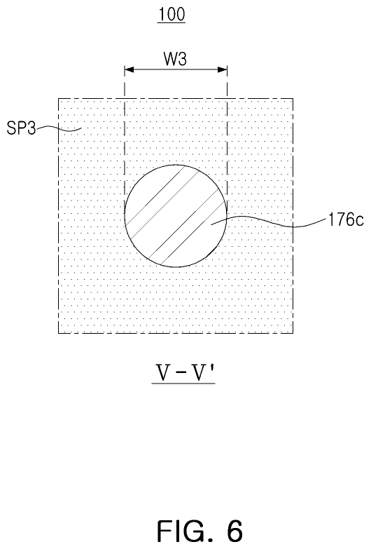

FIG. 3 is an enlarged view of a portion of the semiconductor device illustrated in FIG. 2. FIG. 3 may correspond to region A illustrated in FIG. 2. FIGS. 4, 5, and 6 are cross-sectional views of the semiconductor device illustrated in FIG. 3, taken along lines III-III, IV-IV′, and V-V′, respectively.

Referring further to FIGS. 3 to 6, each lower electrode 170 may include a first electrode material layer 172, a second electrode material layer 174, and a third electrode material layer 176. The first electrode material layer 172 may have a cylindrical shape having an open upper end or surface. The first electrode material layer 172 may pass through the etch stop layer 168, and a lower surface of the first electrode material layer 172 may be in contact with an upper surface of the upper conductive pattern 160. A height of the first electrode material layer 172 may be less than a height H1 of the lower electrode 170. The height may be measured along a direction extending away from (e.g., perpendicular to) a surface of the lower structure or substrate 101. For example, an upper surface 173 of the first electrode material layer 172 may be disposed on a level, lower than that an upper surface of the lower electrode 170. An external surface of the first electrode material layer 172 may be in contact with the support layers SP1, SP2, and SP3 and the dielectric layer 180. An internal surface of the first electrode material layer 172 (e.g., within an interior of the cylindrical shape) may be in contact with the second electrode material layer 174 and the third electrode material layer 176. The first electrode material layer 172 may include at least one of titanium nitride (TiN), titanium oxide (TiO₂), and titanium oxynitride (TION).

The second electrode material layer 174 may be disposed on the internal surface of the first electrode material layer 172. Here, a portion of the first electrode material layer 172 having the second electrode material layer 174 disposed thereon may be referred to as an upper portion 172b, and a portion of the first electrode material layer 172 disposed on the upper portion 172b, the portion of the first electrode material layer 172 not having the second electrode material layer 174 thereon, may be referred to as a lower portion 172a. For example, the second electrode material layer 174 may be disposed on an internal surface of the upper portion 172b of the first electrode material layer 172. In an example embodiment, the second electrode material layer 174 may have a hollow cylindrical shape. For example, the second electrode material layer 174 may have a cylindrical shape having open upper and lower ends or surfaces.

In an example embodiment, an upper end 175a of the second electrode material layer 174 may be disposed on a level, the same as (i.e., coplanar with) that of an upper surface 173 of the first electrode material layer 172. A lower end 175b of the second electrode material layer 174 may be disposed on a level, higher than that of a lower surface of the first electrode material layer 172. In an example embodiment, a distance or height H2 between a lower surface of the lower electrode 170 (that is, a lower surface of the first electrode material layer 172) and the lower end 175b of the second electrode material layer 174 may be about 0.4 to about 0.6 times a distance or height H1 between the lower surface of the lower electrode 170 and the upper surface of the lower electrode 170. In an example embodiment, the second electrode material layer 174 may have a constant or uniform thickness, but the present inventive concept is not limited thereto. The thickness of the second electrode material layer 174 may be greater than 0 Å and less than about 20 Å.

The second electrode material layer 174 may include a material, different from that of the first electrode material layer 172. In an example embodiment, the second electrode material layer 174 may include a material having a dielectric constant, higher than that of the dielectric layer 180. For example, the second electrode material layer 174 may include at least one of niobium nitride (NbN), niobium oxide (NbOx), niobium oxynitride (NbON), tantalum nitride (TaN), tantalum oxide (TaO), lanthanum nitride (LaN), and lanthanum oxide (LaO). The second electrode material layer 174 may improve capacitance of the information storage structure CAP.

The third electrode material layer 176 may be disposed on the first electrode material layer 172 and the second electrode material layer 174. A portion of the third electrode material layer 176 may be surrounded by the first electrode material layer 172 and the second electrode material layer 174, and a portion of the third electrode material layer 176 may be disposed on a level, higher than those of the first electrode material layer 172 and the second electrode material layer 174. Here, a portion of the third electrode material layer 176 in contact with the internal surface of the first electrode material layer 172, the portion of the third electrode material layer 176 surrounded by the first electrode material layer 172, may be referred to as a lower portion 176a. A portion of the third electrode material layer 176 in contact with an internal surface of the second electrode material layer 174, the portion of the third electrode material layer 176 surrounded by the second electrode material layer 174, may be referred to as an intermediate portion 176b. A portion of the third electrode material layer 176 disposed on a level, higher than those of the first electrode material layer 172 and the second electrode material layer 174, the portion of the third electrode material layer 176 surrounded by the support layer SP3, may be referred to as an upper portion 176c. The terms “surround” (or “cover” or “fill”) as may be used herein may not require completely surrounding (or covering or filling) the described elements or layers, but may, for example, refer to partially surrounding (or covering or filling) the described elements or layers.

The lower portion 176a, the intermediate portion 176b, and the upper portion 176c of the third electrode material layer 176 have a first width W1, a second width W2, and a third width W3, respectively. The width may be measured along a direction parallel to a surface of the lower structure or substrate 101. The first width W1 may be greater than the second width W2, and may be less than the third width W3. The lower portion 176a and the upper portion 176c may overlap the second electrode material layer 174 in a vertical (e.g., Z−) direction. Components or layers described with reference to “overlap” in a particular direction may be at least partially obstructed by one another when viewed along a line extending in the particular direction or in a plane perpendicular to the particular direction. The third electrode material layer 176 may include a material having strength or stiffness stronger than those of the first electrode material layer 172 and the second electrode material layer 174. In an example embodiment, the third electrode material layer 176 may include titanium silicide nitride (TiSiN). The third electrode material layer 176 may prevent the lower electrode 170 from collapsing or bending.

As used herein, the lower portion 172a and the upper portion 172b of the first electrode material layer 172 may be referred to as a first lower electrode layer 172a and a first upper electrode layer 172b, respectively. The second electrode material layer 174 may be referred to as an insertion layer 174. The lower portion 176a of the third electrode material layer 176 may be referred to as a third lower electrode layer 176a, and the intermediate portion 176b and the upper portion 176c of the third electrode material layer 176 may also be referred to as third upper electrode layers 176b and 176c.

The lower electrode 170 may include a first structure 170a and a second structure 170b. For example, the first lower electrode layer 172a of the first electrode material layer 172 and the third lower electrode layer 176a of the third electrode material layer 176 may form the first structure 170a of the lower electrode 170. The first upper electrode layer 172b of the first electrode material layer 172, the insertion layer 174, and the third upper electrode layers 176b and 176c may form the second structure 170b of the lower electrode 170.

According to example embodiments of the present inventive concept, the second structure 170b of the lower electrode 170 may include an insertion layer 174 including a material having a dielectric constant, higher than that of the dielectric layer 180. Accordingly, the information storage structure CAP may have improved or increased capacitance. The third lower electrode layer 176a of the third electrode material layer 176, included in the first structure 170a of the lower electrode 170, may have a first width W1, and the first width W1 may be greater than a second width W2 of a portion 176b of the third electrode material layer 176 disposed between the insertion layer 174 of the second structure 170b of the lower electrode 170. That is, the first (lower) structure 170a of the lower electrode 170 may be free of the insertion layer 174, such that the greater first width W1 may be retained in combination with the increase in capacitance provided by the insertion layer 174 on the second (upper) structure 170b. Accordingly, even when some support layers, among the support layers SP1, SP2, and SP3, do not directly contact with a side surface of the first structure 170a and do not support the first structure 170a, bending of the first structure 170a of the lower electrode 170 may be prevented.

The dielectric layer 180 may cover a side surface and an upper surface of each of the lower electrodes 170, on the surfaces of the lower electrodes 170. The dielectric layer 180 may be disposed between the lower electrodes 170 and the upper electrode 190. The dielectric layer 180 may cover upper surfaces and lower surfaces of the support layers SP1, SP2, and SP3. The dielectric layer 180 may cover an upper surface of the etch stop layer 168.

The dielectric layer 180 may include a high-K dielectric material, silicon oxide, silicon nitride, or combinations thereof. However, in some example embodiments, the dielectric layer 180 may include an oxide, nitride, silicide, oxynitride, or silicified oxynitride including at least one or combinations of titanium (Ti) doped with fluorine (F), tantalum (Ta), hafnium (Hf), aluminum (Al), zirconium (Zr), and lanthanum (La).

The upper electrode 190 may cover a plurality of lower electrodes 170, the support layers SP1, SP2, and SP3, and the dielectric layer 180. The upper electrode 190 may fill a space between the plurality of lower electrodes 170 and a space between the support layers SP1, SP2, and SP3. The upper electrode 190 may be in direct contact with the dielectric layer 180.

In an example embodiment, the upper electrode 190 may include a lower conductive layer 192, and an upper conductive layer 194 on the lower conductive layer 192. The lower conductive layer 192 may conformally cover the dielectric layer 180. The upper conductive layer 194 may fill the space between the plurality of lower electrodes 170 and the space between the support layers SP1, SP2, and SP3. The lower conductive layer 192 may include at least one of TiN, NbN, WN, VN, MON, TaN, TiSiN, and TiCN. The upper conductive layer 194 may include a silicon material or a silicon-germanium material.

The support layers SP1, SP2, and SP3 may include a first support layer SP1, a second support layer SP2 on the first support layer SP1, and a third support layer SP3 on the second support layer SP2. The support layers SP1, SP2, and SP3 may be spaced apart from the substrate 101 in a direction (vertical direction) that is perpendicular to the upper surface of the substrate 101. The support layers SP1, SP2, SP3 may be in contact with the lower electrodes 170, and may extend in a direction (horizontal direction) that is parallel to the upper surface of the substrate 101.

The support layers SP1, SP2, and SP3 may be in direct contact with the lower electrodes 170 and the dielectric layer 180. The third support layer SP3 may have a thickness, greater than those of the first support layer SP1 and the second support layer SP2, but the present inventive concept is not limited thereto. The support layers SP1, SP2, and SP3 may be layers supporting the lower electrodes 170 having a high aspect ratio. The support layers SP1, SP2, and SP3 may respectively include, for example, at least one of silicon nitride and silicon oxynitride, or a material similar thereto. The number, thickness, and/or arrangement of the support layers SP1, SP2, and SP3 are not limited to those illustrated, and may be changed in various manners in some example embodiments.

An upper surface of the third support layer SP3 may be coplanar with upper surfaces of the lower electrodes 170. In an example embodiment, the upper surface 173 of the first electrode material layer 172 and the upper end 175a of the second electrode material layer 174 may be disposed on a level, the same as (i.e., coplanar with) that of a lower surface of the third support layer SP3, but the present inventive concept is not limited thereto. In an example embodiment, the lower end 175b of the second electrode material layer 174 may overlap the first support layer SP1 in a horizontal direction, but the present inventive concept is not limited thereto.

As illustrated in FIG. 1, the support layers SP1, SP2, and SP3 may be disposed between the lower electrodes 170, and may support the lower electrodes 170. The support layers SP1, SP2, and SP3 may respectively include supporter holes SH. In FIG. 1, it is illustrated that each supporter hole SH is disposed between four adjacent lower electrodes 170, but the present inventive concept is not limited thereto. The shape and arrangement of the supporter holes SH may be changed in some example embodiments.

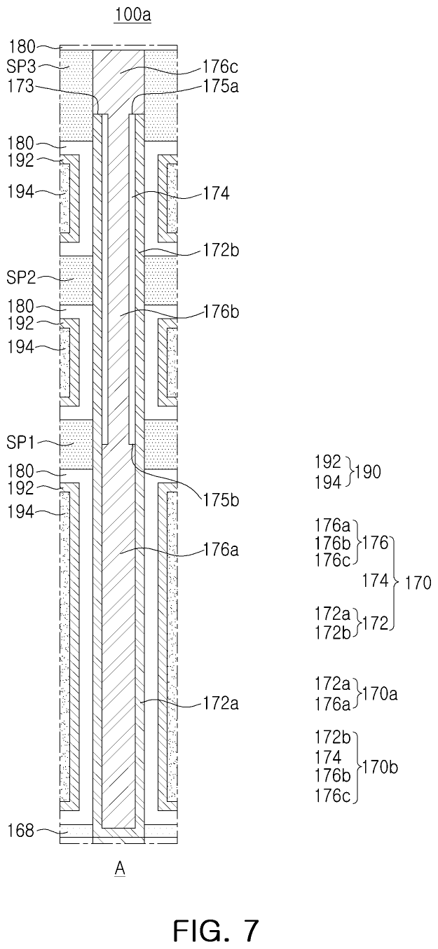

FIGS. 7 to 11 are vertical cross-sectional views of semiconductor devices according to example embodiments.

Referring to FIG. 7, a lower electrode 170 of a semiconductor device 100a may include a second electrode material layer 174 between a first electrode material layer 172 and a third electrode material layer 176. In an example embodiment, an upper surface 173 of the first electrode material layer 172 and an upper end 175a of the second electrode material layer 174 may be disposed on a level, different from (i.e., non-coplanar with) that of a lower surface of a third support layer SP3, for example, on a level, higher than that of the lower surface of the third support layer SP3. A vertical height or thickness of an upper portion 176c of the third electrode material layer 176 may be less than a vertical height or thickness of the third support layer SP3.

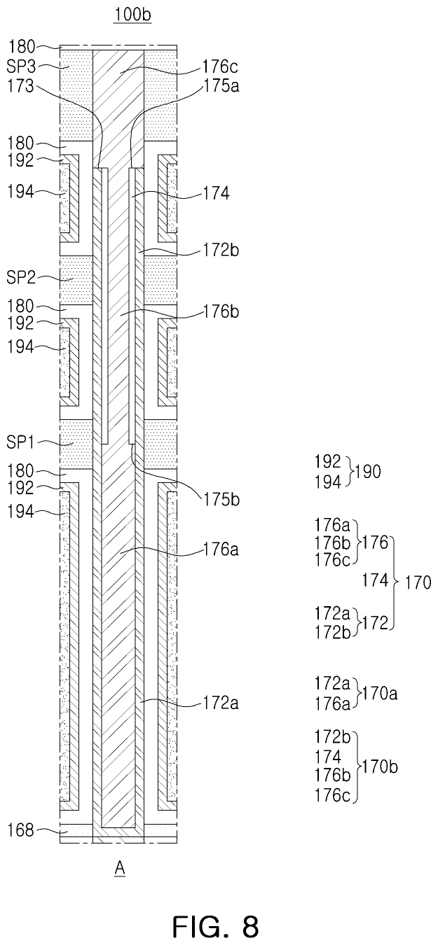

Referring to FIG. 8, a lower electrode 170 of a semiconductor device 100b may include a second electrode material layer 174 between a first electrode material layer 172 and a third electrode material layer 176. In an example embodiment, an upper surface 173 of the first electrode material layer 172 and an upper end 175a of the second electrode material layer 174 may be disposed on a level, different from (i.e., non-coplanar with) that of a lower surface of a third support layer SP3, for example, on a level, lower than that of the lower surface of the third support layer SP3. A vertical height or thickness of an upper portion 176c of the third electrode material layer 176 may be greater than a vertical height or thickness of the third support layer SP3. A side surface of the upper portion 176c of the third electrode material layer 176 may be in contact with a dielectric layer 180.

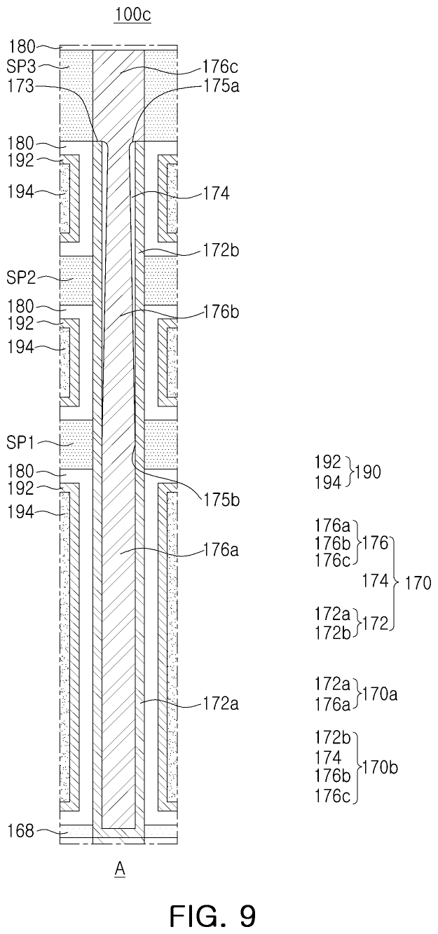

Referring to FIG. 9, a lower electrode 170 of a semiconductor device 100c may include a second electrode material layer 174 between a first electrode material layer 172 and a third electrode material layer 176. In an example embodiment, the second electrode material layer 174 may not have a constant thickness (i.e., may have a non-uniform thickness). For example, the thickness of the second electrode material layer 174 may downwardly decrease in a direction toward the substrate 101. A side surface of the second electrode material layer 174 may include a curved surface. A width of an intermediate portion 176b of the third electrode material layer 176 may upwardly decrease in a direction away from the substrate 101.

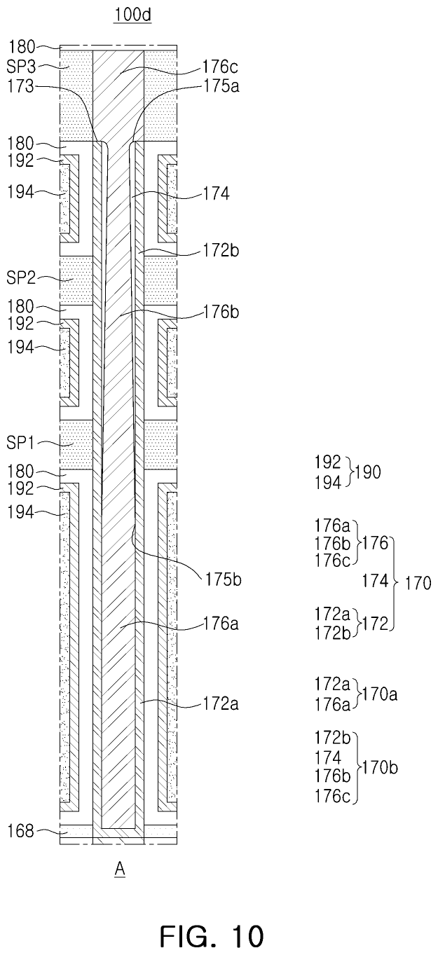

Referring to FIG. 10, a lower electrode 170 of a semiconductor device 100d may include a second electrode material layer 174 between a first electrode material layer 172 and a third electrode material layer 176. In an example embodiment, a lower end 175b of the second electrode material layer 174 may be disposed on a level, different from that of a first support layer SP1, for example, on a level, lower than that of the first support layer SP1 relative to the substrate 101. For example, a first structure 170a of the lower electrode 170 may be spaced apart from support layers SP1, SP2, and SP3, and may not be in contact with the support layers SP1, SP2, and SP3, e.g., the first structure 170a of the lower electrode 170 may be below the lowermost support layer SP1.

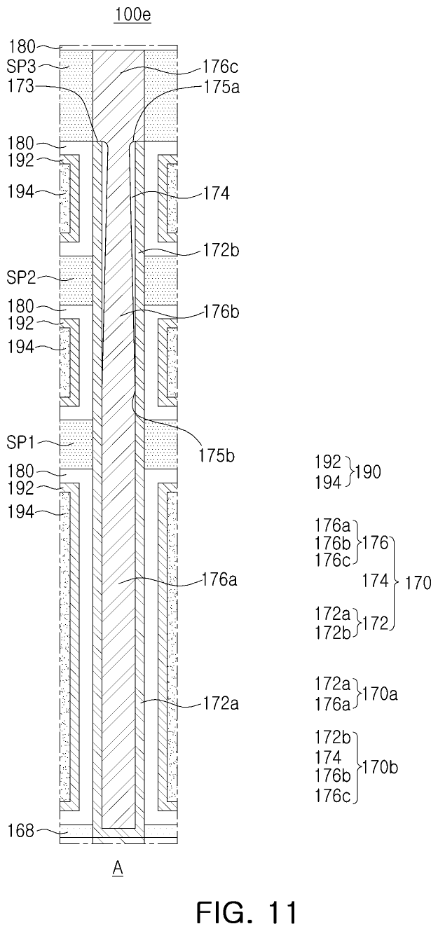

Referring to FIG. 11, a lower electrode 170 of a semiconductor device 100e may include a second electrode material layer 174 between a first electrode material layer 172 and a third electrode material layer 176. In an example embodiment, a lower end 175b of the second electrode material layer 174 may be disposed on a level, different from that of a first support layer SP1, for example, on a level, higher than that of the first support layer SP1. For example, a first structure 170a of the lower electrode 170 may be in contact with the first support layer SP1, and a second structure 170b of the lower electrode 170 may be spaced apart from the first support layer SP1, and may not be in contact with the first support layer SP1.

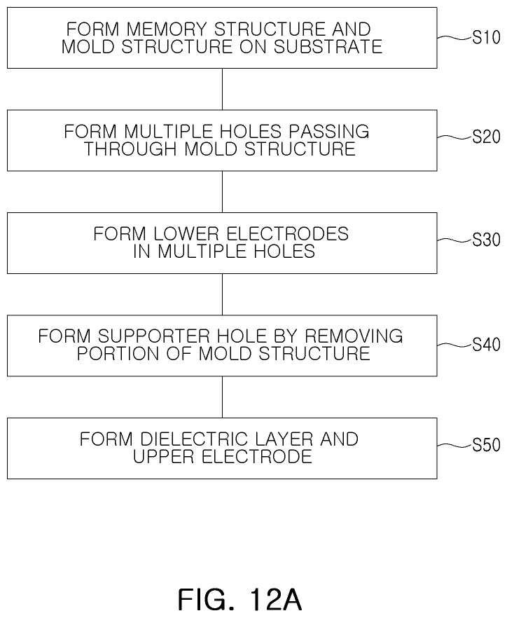

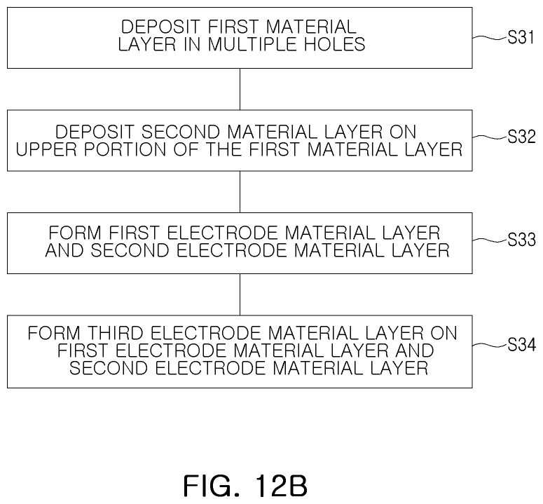

FIGS. 12A and 12B are flowcharts of a method of forming a semiconductor device according to an example embodiment.

Referring to FIG. 12A, a semiconductor device manufacturing method according to an example embodiment may include forming a lower structure and a mold structure on a substrate (S10), forming a plurality of holes passing through the mold structure (S20), forming lower electrodes in the plurality of holes (S30), removing a portion of the mold structure to form a supporter hole (S40), and forming a dielectric layer and an upper electrode (S50).

Referring further to FIG. 12B, the forming the lower electrodes in the plurality of holes (S30) may include depositing a first material layer in the plurality of holes (S31), depositing a second material layer on an upper portion of the first material layer (S32), etching the first material layer and the second material layer to form a first electrode material layer and a second electrode material layer (S33), and forming a third electrode material layer on the first electrode material layer and the second electrode material layer (S34).

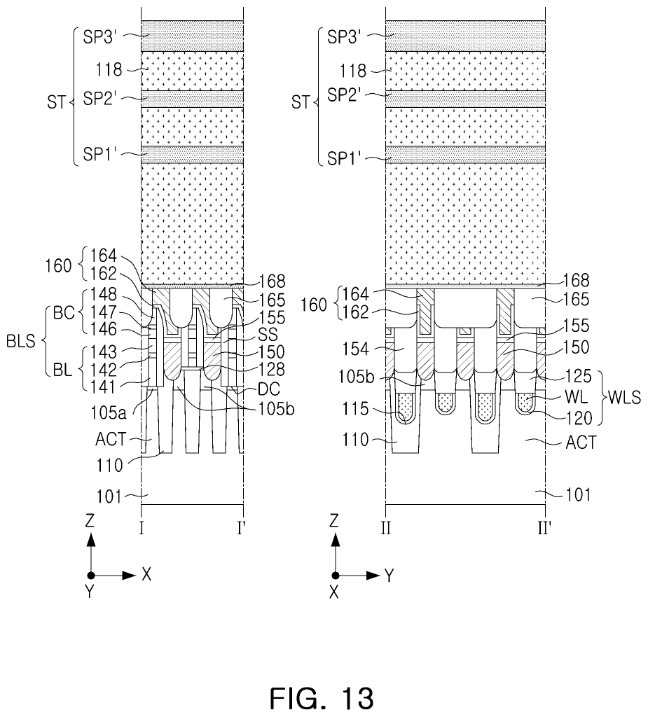

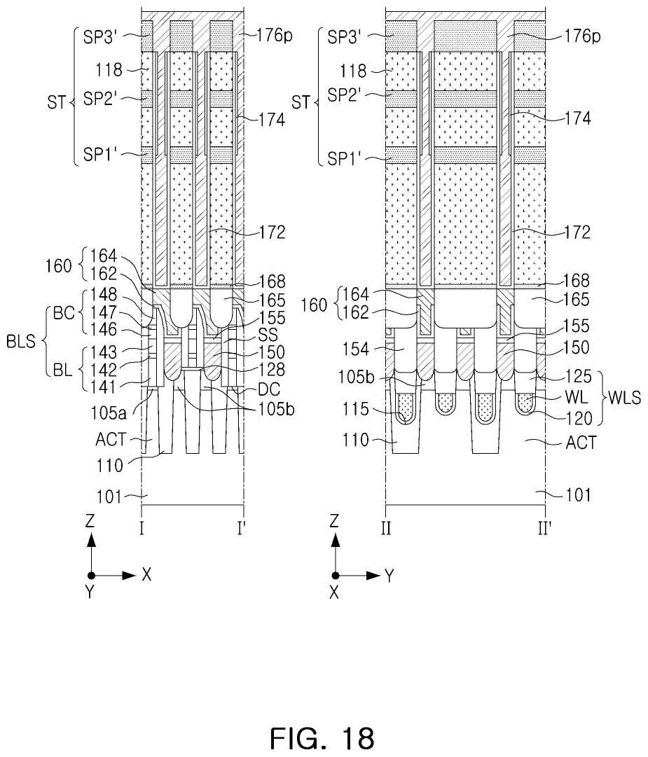

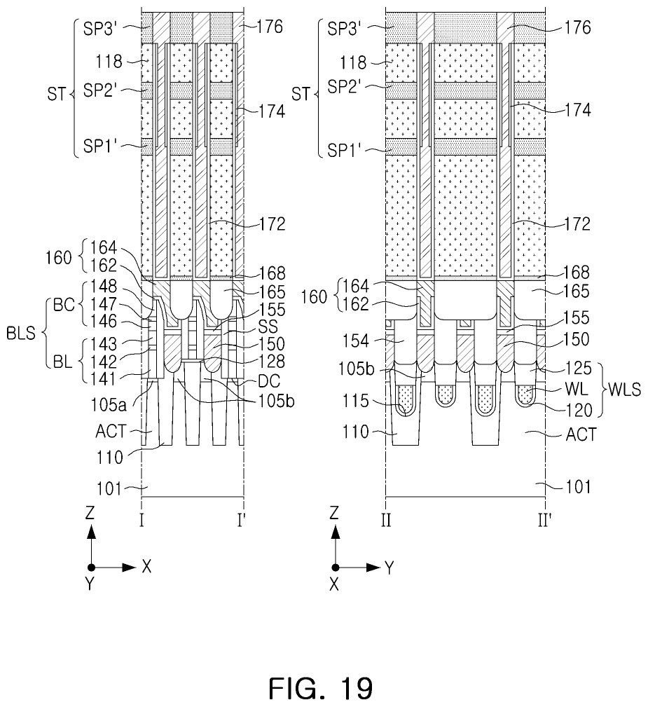

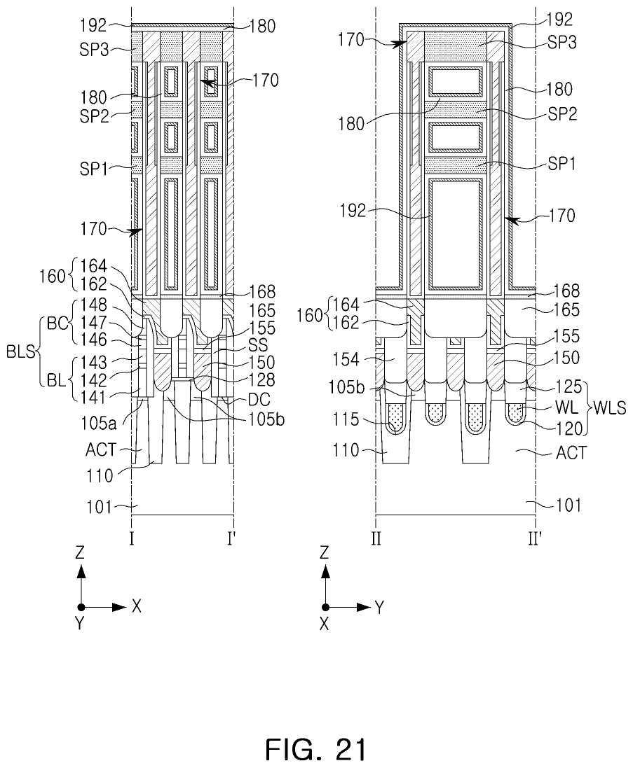

FIGS. 13 to 21 are vertical cross-sectional views of sequential processes of a method of manufacturing a semiconductor device according to an example embodiment.

Referring to FIGS. 12A and 13, a lower structure and a mold structure ST may be formed on a substrate (S10). An isolation layer 110 may be formed on the substrate 101 to define an active region ACT. An isolation trench may be formed in the substrate 101, and the isolation layer 110 may fill the isolation trench. In plan view, the active region ACT may have an elongated bar shape extending in a direction, oblique to a direction of extension of a word line WL. Impurity regions may be formed on an upper portion of the active region ACT by performing an ion implantation process using the isolation layer 110 as an ion implantation mask. The active region ACT and the isolation layer 110 may be patterned to form a gate trench 115. A pair of gate trenches 115 may cross the active region ACT, but present inventive concept is not limited thereto. The impurity regions may also be isolated from each other by the gate trench 115 to form a first impurity region 105a and a second impurity region 105b.

A gate dielectric layer 120, having a substantially conformal thickness, may be formed on an internal surface of the gate trench 115. Subsequently, the word line WL may be formed to fill at least a portion of the gate trench 115. An upper surface of the word line WL may be recessed to be lower than an upper surface of the active region ACT. A gate capping layer 125 may be formed on the word line WL by stacking an insulating layer on the substrate 101 to fill the gate trench 115, and etching the insulating layer.

An insulating layer and a conductive layer may be sequentially formed on a front surface of the substrate 101 and patterned to form a buffer insulating layer 128 and a first conductive pattern 141 that are sequentially stacked. The buffer insulating layer 128 may be formed of at least one of silicon oxide, silicon nitride, and silicon oxynitride. A plurality of buffer insulating layers 128 may be formed to be spaced apart from each other. The first conductive pattern 141 may have a shape corresponding to a planar shape of the buffer insulating layer 128. The buffer insulating layer 128 may be formed to simultaneously cover ends of two adjacent active regions ACT, that is, adjacent second impurity regions 105b. A bit line contact hole may be formed by etching upper portions of the isolation layer 110, the substrate 101, and the gate capping layer 125, using the buffer insulating layer 128 and the first conductive pattern 141 as an etching mask. The bit line contact hole may expose the first impurity region 105a.

A bit line contact pattern DC, filling the bit line contact hole, may be formed. Forming the bit line contact pattern DC may include forming a conductive layer filling the bit line contact hole, and performing a planarization process. As an example, the bit line contact pattern DC may be formed of polysilicon. A second conductive pattern 142, a third conductive pattern 143, and first to third capping patterns 146, 147, and 148 may be sequentially formed on the first conductive pattern 141, and then the first to third conductive patterns 141, 142, and 143 may be sequentially etched, using the first to third capping patterns 146, 147, and 148 as an etching mask. As a result, a bit line structure BLS, including a bit line BL including the first to third conductive patterns 141, 142, and 143 and a bit line capping pattern BC including the first to third capping patterns 146, 147, and 148, may be formed.

A spacer structure SS may be formed on side surfaces of the bit line structure BLS. The spacer structure SS may be formed of a plurality of layers. Fence insulating patterns 154 may be formed between the spacer structures SS. The fence insulating patterns 154 may include silicon nitride or silicon oxynitride. An opening, exposing the second impurity region 105b, may be formed by performing an anisotropic etching process, using the fence insulating patterns 154 and a third capping pattern 148 as an etching mask.

A lower conductive pattern 150 may be formed on a lower portion of the opening. The lower conductive pattern 150 may be formed of a semiconductor material such as polysilicon. As an example, the lower conductive pattern 150 may be formed by forming a polysilicon layer filling the opening, and then performing an etch-back process.

The metal-semiconductor compound layer 155 may be formed on the lower conductive pattern 150. The formation of the metal-semiconductor compound layer 155 may include a metal layer deposition process and a heat treatment process.

An upper conductive pattern 160 may be formed on an upper portion of the opening. Forming the upper conductive pattern 160 may include sequentially forming a barrier layer 162 and a conductive layer 164. Thereafter, a patterning process may be performed on the barrier layer 162 and the conductive layer 164 to form the insulating patterns 165 passing therethrough. Accordingly, a lower structure, including the substrate 101, a word line structure WLS, and the bit line structure BLS, may be formed.

An etch stop layer 168 may be conformally formed on the lower structure, and mold layers 118 and preliminary support layers SP1′, SP2′, and SP3′ may be alternately stacked on the etch stop layer 168. The mold layers 118 and the preliminary support layers SP1′, SP2′, and SP3′ may form the mold structure ST. The etch stop layer 168 may include the mold layers 118 and an insulating material, for example, at least one of silicon oxide, silicon nitride, silicon carbide, silicon oxycarbide, and silicon carbonitride, having an etch selectivity under a specific etch condition. The mold layers 118 may be formed of silicon oxide, and the preliminary support layers SP1′, SP2′, and SP3′ may be formed of silicon nitride.

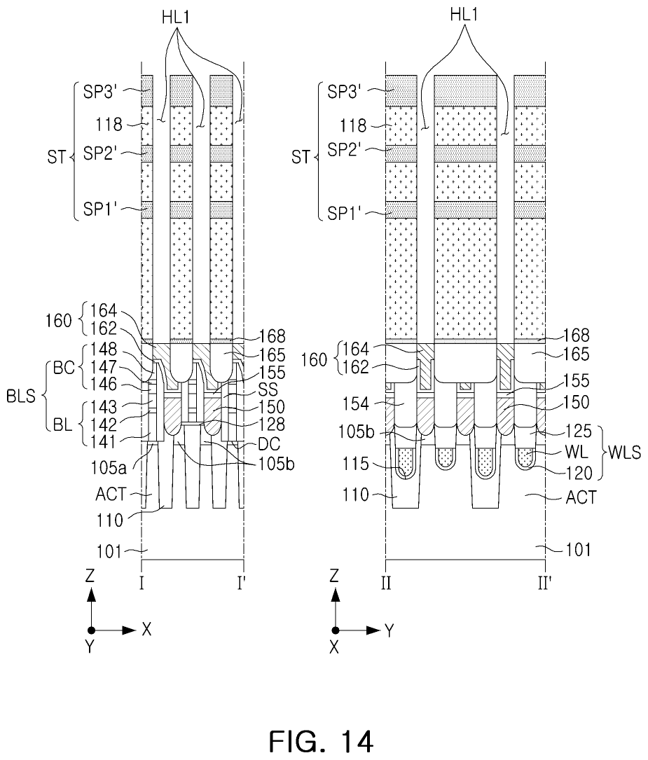

Referring to FIGS. 12A and 14, a plurality of holes HL1, passing through the mold structure ST, may be formed (S20). An anisotropic etching process may be performed to form a plurality of holes HL1, and the etch stop layer 168 may serve as a stopper to stop the etching process. The plurality of holes H1 may pass through the etch stop layer 168 to expose the upper conductive patterns 160. The plurality of holes H1, regions in which lower electrodes 170 are to be formed, may be spaced apart from each other at predetermined intervals on a plane, and thus may be formed in a regular arrangement, as illustrated in FIG. 1.

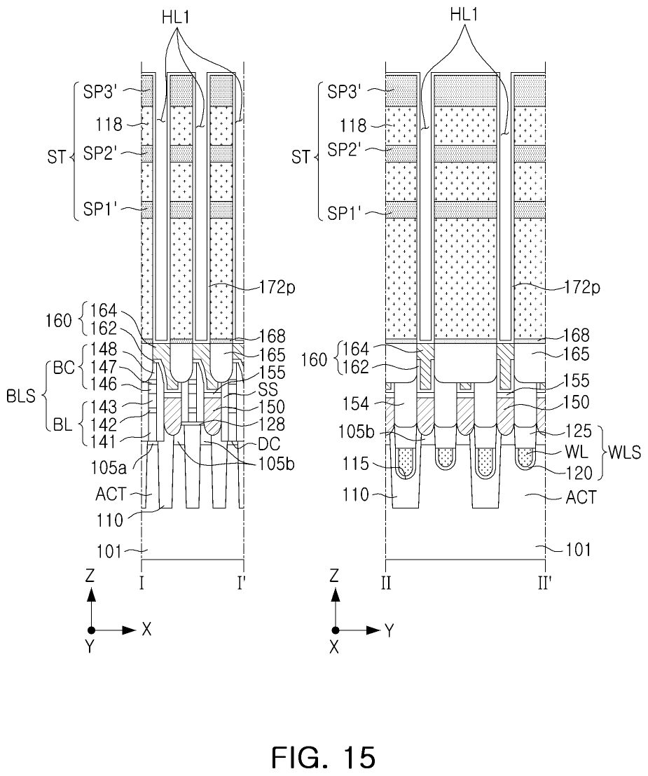

Thereafter, the lower electrodes 170 may be formed in the plurality of holes HL1 (S30). Referring further to FIGS. 12B and 15, a first material layer 172p may be deposited in the plurality of holes HL1 (S31). The first material layer 172p may cover internal walls of the plurality of holes HL1, upper surfaces of the insulating patterns 165, and an upper surface of the preliminary support layer SP3′. The first material layer 172p may be conformally formed, and the first material layer 172p may have a constant thickness. The first material layer 172p may include titanium nitride (TiN).

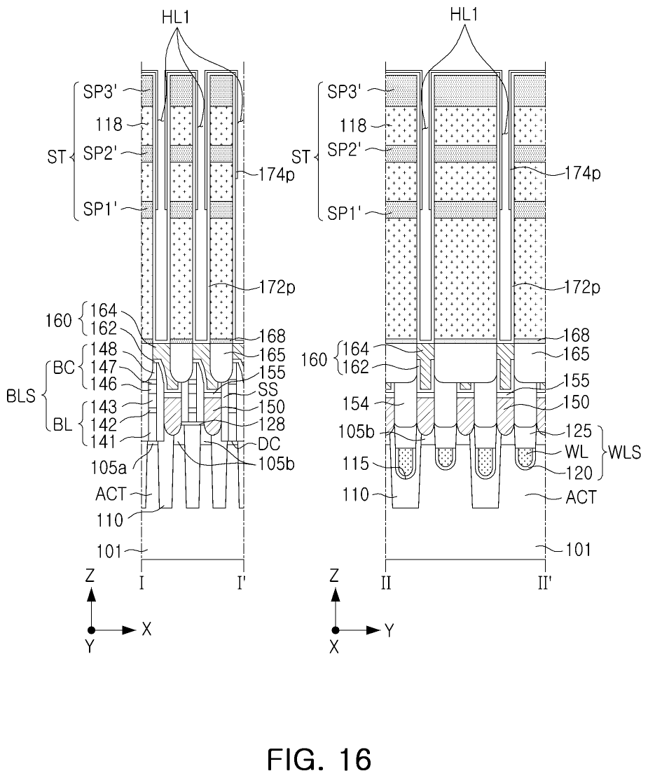

Referring further to FIGS. 12B and 16, a second material layer 174p may be deposited on an upper portion of the first material layer 172p (S32). The second material layer 174p may be formed using a deposition method such as a chemical vapor deposition (CVD) method or an atomic layer deposition method. In an example embodiment, the second material layer 174p may be deposited to have low step coverage. For example, the second material layer 174p may not be deposited on a lower portion of the first material layer 172p, but may be deposited on the upper portion of the first material layer 172p and the upper surface of the preliminary support layer SP3′. That is, the second material layer 174p may extend along the upper portion of the first material layer 172p, but the lower portion of the first material layer 172p may be free of the second material layer 174p. The second material layer 174p may include at least one of niobium nitride (NbN), tantalum nitride (TaN), and lanthanum nitride (LaN).

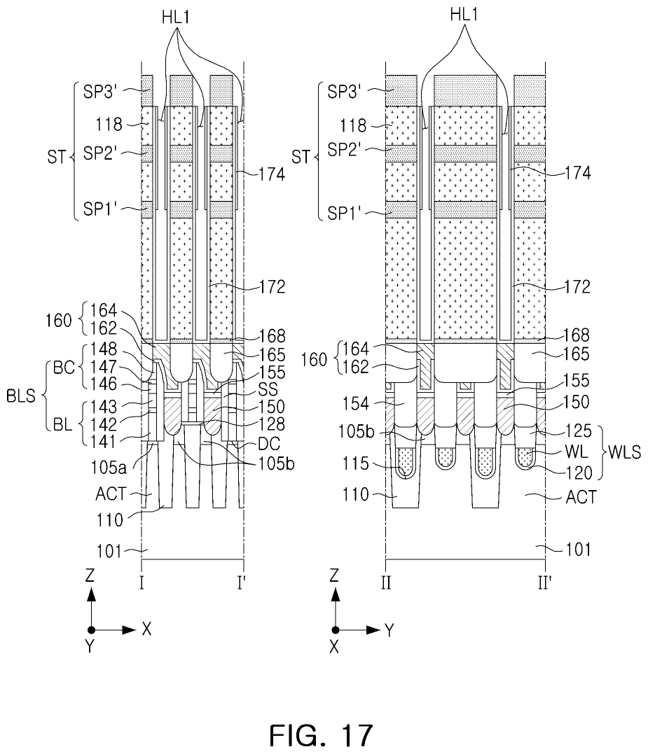

Referring further to FIGS. 12B and 17, the first material layer 172p and the second material layer 174p may be etched to form a first electrode material layer 172 and a second electrode material layer 174 (S33). For example, an etch-back process may be performed, upper portions of the first material layer 172p and the second material layer 174p may be etched, and upper and side surfaces of the preliminary support layer SP3′ may be exposed.

Referring further to FIGS. 12B, 18, and 19, a third electrode material layer may be formed on the first electrode material layer 172 and the second electrode material layer 174 (S34). First, a third material layer 176p may be deposited on the first electrode material layer 172 and the second electrode material layer 174. The third material layer 176p may fill the plurality of holes HL1, and may cover the upper and side surfaces of the preliminary support layer SP3′.

Thereafter, the third material layer 176p may be etched to form a third electrode material layer 176. For example, an etch-back process may be performed, an upper portion of the third material layer 176p may be etched, and the upper surface of the preliminary support layer SP3′ may be exposed. An upper surface of the third electrode material layer 176 may be coplanar with the upper surface of the preliminary support layer SP3′.

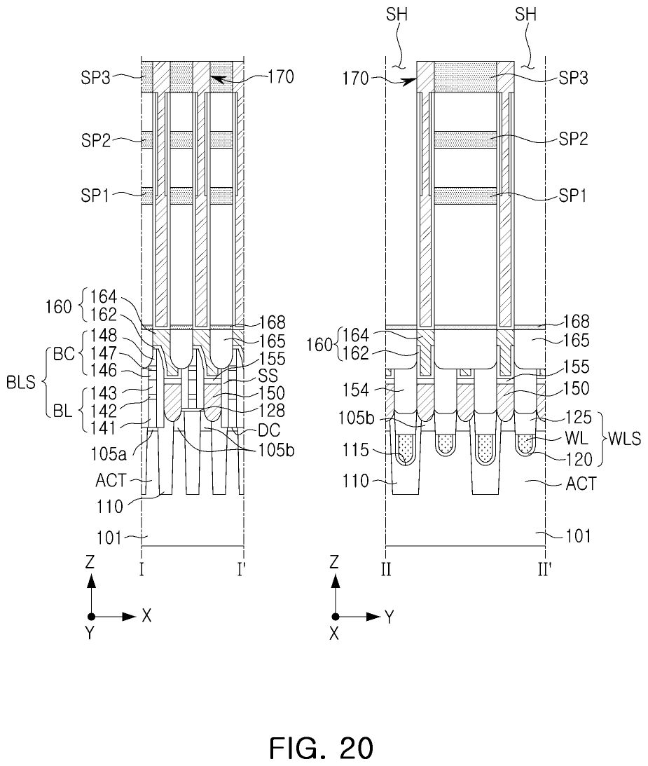

Referring to FIGS. 12A and 20, a supporter hole SH may be formed by removing a portion of the mold structure ST (S40). As illustrated in FIG. 1, support layers SP1, SP2, and SP3, having a supporter hole SH, may be formed by etching the preliminary support layers SP1′, SP2′, and SP3′. In an example embodiment, the support layers SP1, SP2, and SP3 may have support holes SH having the same pattern, but the present inventive concept is not limited thereto. The mold layers 118 between the support layers SP1, SP2, and SP3 may be selectively removed to expose a lower electrode 170 including the first electrode material layer 172, the second electrode material layer 174, and the third electrode material layer 176. In example embodiments, a process of removing the mold layers 118 may be performed by a wet etching process using an etchant (for example, hydrogen fluoride (HF) solution). After the mold layers 118 are removed, an oxidation process may be performed. All or a portion of materials of the first electrode material layer 172 and the second electrode material layer 174 may be oxidized using the oxidation process. For example, the first electrode material layer 172 may include at least one of titanium nitride (TiN), titanium oxide (TiO₂), and titanium oxynitride (TION). The second electrode material layer 174 may include at least one of niobium nitride (NbN), niobium oxide (NbOx), niobium oxynitride (NbON), tantalum nitride (TaN), tantalum oxide (TaO), lanthanum nitride (LaN), and lanthanum oxide (LaO).

Referring to FIGS. 12A, 21, and 2, a dielectric layer 180 and an upper electrode 190 may be formed (S50). The dielectric layer 180 may cover side and upper surfaces of each of the lower electrodes 170, and upper and lower surfaces of the support layers SP1, SP2, and SP3. The dielectric layer 180 may also cover an upper surface of the etch stop layer 168.

A lower conductive layer 192 may be conformally formed on the dielectric layer 180. Thereafter, an upper conductive layer 194 may be formed on the lower conductive layer 192 to form the upper electrode 190. The upper conductive layer 194 may fill a space between the lower electrodes 170, and may cover the lower electrodes 170 and the support layers SP1, SP2, and SP3.

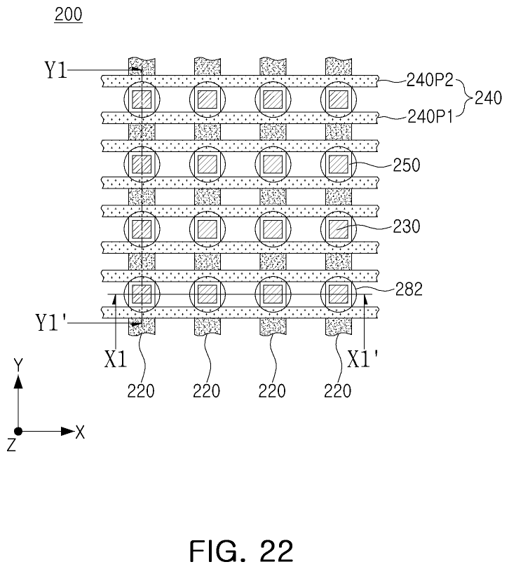

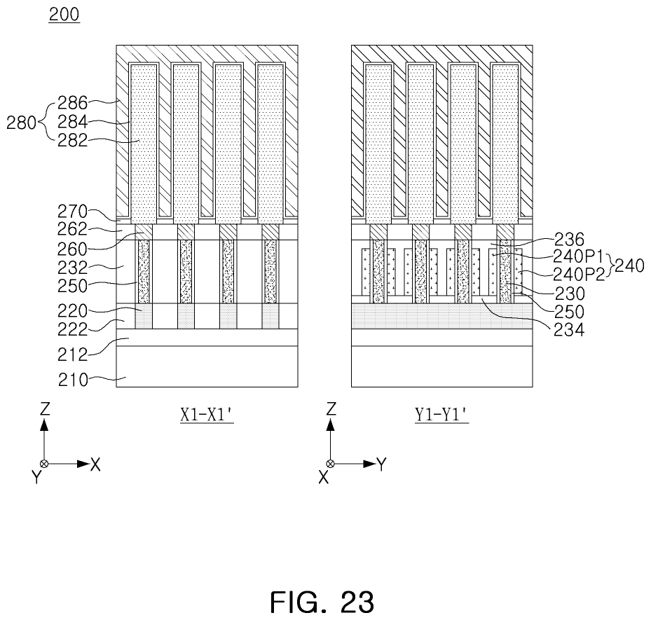

FIG. 22 is a plan view of an integrated circuit device according to example embodiments. FIG. 23 is a vertical cross-sectional view of the integrated circuit device illustrated in FIG. 10, taken along lines X1-X1′ and Y1-Y1′.

Referring to FIGS. 22 and 23, an integrated circuit device 200 may include a substrate 210, a plurality of first conductive lines 220, a channel layer 230, a gate electrode 240, a gate insulating layer 250, and an information storage structure 280. The integrated circuit device 200 may be a memory device including a vertical channel transistor (VCT). The vertical channel transistor may refer to a structure in which a channel length of the channel layer 230 extends from the substrate 210 in a vertical direction.

A lower insulating layer 212 may be disposed on the substrate 210. On the lower insulating layer 212, the plurality of first conductive lines 220 may be spaced apart from each other in a first direction (X-direction), and may extend in a second direction (Y-direction). A plurality of first insulating patterns 222 may be disposed on the lower insulating layer 212 to fill a space between the plurality of first conductive lines 220. The plurality of first insulating patterns 222 may extend in the second direction (Y-direction), and upper surfaces of the plurality of first insulating patterns 222 may be disposed on a level, the same as that of each of upper surfaces of the plurality of first conductive lines 220. The plurality of first conductive lines 220 may function as bit lines of the integrated circuit device 200.

In example embodiments, the plurality of first conductive lines 220 may include doped polysilicon, a metal, a conductive metal nitride, a conductive metal silicide, a conductive metal oxide, or combinations thereof. For example, the plurality of first conductive lines 220 may include doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOₓ, RuOₓ, or combinations thereof, but the present inventive concept is not limited thereto. The plurality of first conductive lines 220 may include a single layer or multiple layers formed of the above-described materials. In example embodiments, the plurality of first conductive lines 220 may include a two-dimensional (2D) semiconductor material. For example, the 2D semiconductor material may include graphene, carbon nanotubes, or a combination thereof.

The channel layer 230 may be arranged on the plurality of first conductive lines 220 in a matrix form of being spaced apart from each other in a first direction (X-direction) and a second direction (Y-direction). The channel layer 230 may have a first width in the first direction (X-direction) and a first height in a third direction (Z-direction), and the first height may be greater than the first width. For example, the first height may be about 2 to 10 times the first width, but the present inventive concept is not limited thereto. A bottom portion of the channel layer 230 may function as a first source/drain region (not illustrated), an upper portion of the channel layer 230 may function as a second source/drain region (not illustrated), and a portion of the channel layer 230 between the first and second source/drain regions may function as a channel region (not illustrated). The first source/drain region and the second source/drain region may be vertically spaced apart from each other, and the channel region may be a vertical channel region.

In example embodiments, the channel layer 230 may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or combinations thereof. The channel layer 230 may include a single layer or multiple layers of the oxide semiconductor. In some examples, the channel layer 230 may have a bandgap energy, greater than that of silicon. For example, the channel layer 230 may have a bandgap energy of about 1.5 eV to about 5.6 eV. For example, the channel layer 230 may have improved or optimal channel performance, when the channel layer 230 has a bandgap energy of about 2.0 eV to 4.0 eV. For example, the channel layer 230 may be polycrystalline or amorphous, but the present inventive concept is not limited thereto. In example embodiments, the channel layer 230 may include a 2D semiconductor material. For example, the 2D semiconductor material may include graphene, carbon nanotubes, or a combination thereof.

The gate electrode 240 may extend on opposite sidewalls of the channel layer 230 in the first direction (X-direction). The gate electrode 240 may include a first sub-gate electrode 240P1 opposing a first sidewall of the channel layer 230, and a second sub-gate electrode 240P2 opposing a second sidewall opposite to the first sidewall of the channel layer 230. As one channel layer 230 is disposed between the first sub-gate electrode 240P1 and the second sub-gate electrode 240P2, the integrated circuit device 200 may have a dual-gate transistor structure. However, the present inventive concept is not limited thereto, and the second sub-gate electrode 240P2 may be omitted and only the first sub-gate electrode 240P1, opposing the first sidewall of the channel layer 230, may be formed (or vice versa) to implement a single gate transistor structure.

The gate electrode 240 may include doped polysilicon, a metal, a conductive metal nitride, a conductive metal silicide, a conductive metal oxide, or combinations thereof. For example, the gate electrode 240 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ or combinations thereof, but the present inventive concept is not limited thereto.

The gate insulating layer 250 may surround a sidewall of the channel layer 230, and may be interposed between the channel layer 230 and the gate electrode 240. For example, as illustrated in FIG. 23, the entire sidewall of the channel layer 230 may be surrounded by the gate insulating layer 250, and a portion of a sidewall of the gate electrode 240 may be in contact with the gate insulating layer 250. In other example embodiments, the gate insulating layer 250 may extend in a direction of extension of the gate electrode 240 (that is, the first direction (X-direction)), and only two sidewalls opposing the gate electrode 240, among sidewalls of the channel layer 230, may be in contact with the gate insulating layer 250.

In example embodiments, the gate insulating layer 250 may be formed of a silicon oxide film, a silicon oxynitride film, a high-k dielectric film having a dielectric constant higher than that of the silicon oxide film, or combinations thereof. The high-K dielectric film may be formed of a metal oxide or a metal oxynitride. For example, the high-K dielectric film, usable as the gate insulating layer 250, may be formed of HfO₂, HfSiO, HfSiON, HfTaO, HfTIO, HfZrO, ZrO₂, Al₂O₃, or combinations thereof, but the present inventive concept is not limited thereto.

A plurality of second insulating patterns 232 may extend on the plurality of first insulating patterns 222 in the second direction (Y-direction), and the channel layer 230 may be disposed between two adjacent second insulating patterns 232, among the plurality of second insulating patterns 232. In addition, between the two adjacent second insulating patterns 232, a first buried layer 234 and a second buried layer 236 may be disposed in a space between two adjacent channel layers 230. The first buried layer 234 may be disposed on a bottom portion of the space between the two adjacent channel layers 230, and the second buried layer 236 may be disposed on the first buried layer 234 to fill a remainder of the space between the two adjacent channel layers 230. A upper surface of the second buried layer 236 may be disposed on a level, the same as that of a upper surface of the channel layer 230, and the second buried layer 236 may cover an upper surface of the gate electrode 240. Alternatively, the plurality of second insulating patterns 232 may be formed as a material layer continuous with the plurality of first insulating patterns 222, or the second buried layer 236 may be formed as a material layer continuous with the first buried layer 234.

A storage contact 260 may be disposed on the channel layer 230. The storage contact 260 may vertically overlap the channel layer 230, and may be arranged in a matrix form of being spaced apart from each other in the first direction (X-direction) and the second direction (Y-direction). The storage contact 260 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or combinations thereof, but the present inventive concept is not limited thereto. The upper insulating layer 262 may surround a sidewall of the storage contact 260 on the plurality of second insulating patterns 232 and the second buried layer 236.

An etch stop film 270 may be disposed on the upper insulating layer 262, and the information storage structure 280 may be disposed on the etch stop film 270. The information storage structure 280 may include a lower electrode 282, a dielectric layer 284, and an upper electrode 286.

The lower electrode 282 may pass through the etch stop film 270 to be electrically connected to an upper surface of the storage contact 260. The lower electrode 282 may be formed as a pillar-type electrode extending in the third direction (Z-direction), but the present inventive concept is not limited thereto. In example embodiments, the lower electrode 282 may vertically overlap the storage contact 260, and may be arranged in a matrix form of being spaced apart from each other in the first direction (X-direction) and the second direction (Y-direction). Alternatively, a landing pad (not illustrated) may be further disposed between the storage contact 260 and the lower electrode 282, such that the lower electrode 282 may be arranged to have a hexagonal shape.

In the integrated circuit device 200, the lower electrode 282 of the information storage structure 280 may include a first electrode material layer (corresponding to 172 in FIG. 3), a second electrode material layer (corresponding to 174 in FIG. 3), and a third electrode material layer (corresponding to 176 in FIG. 3).

According to example embodiments of the present inventive concept, a lower electrode of an information storage structure may include a second electrode material layer between a first electrode material layer and a third electrode material layer. The second electrode material layer may have a dielectric constant, higher than that of a dielectric layer, and may be disposed on an internal surface of an upper portion of the first electrode material layer, thereby preventing bending of the lower electrode and improving capacitance of the information storage structure.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

While example embodiments have been shown and described above, it will be apparent to those skilled in the art that modifications and variations could be made without departing from the scope of the present inventive concept as defined by the appended claims.

What is claimed is:

1. A semiconductor device comprising:
a lower structure having a conductive region; and
an information storage structure electrically connected to the conductive region,
wherein the information storage structure comprises:
a lower electrode electrically connected to the conductive region;
a dielectric layer on the lower electrode; and
an upper electrode on the dielectric layer,
wherein the lower electrode comprises a first electrode material layer, a second electrode material layer, and a third electrode material layer,
wherein the first electrode material layer extends on at least a portion of a side surface of the third electrode material layer, and a bottom surface of the third electrode material layer, and
wherein the second electrode material layer is between an upper portion of the first electrode material layer and the third electrode material layer.

2. The semiconductor device of claim 1, wherein the first electrode material layer comprises at least one of TiN or TION, and the third electrode material layer comprises TiSiN.

3. The semiconductor device of claim 1, wherein the second electrode material layer comprises a material having a dielectric constant that is higher than that of the dielectric layer.

4. The semiconductor device of claim 3, wherein the second electrode material layer comprises at least one of NbN, NbO, NbON, TaN, TaO, LaN, or LaO.

5. The semiconductor device of claim 1, wherein a thickness of the second electrode material layer is less than about 20 Å.

6. The semiconductor device of claim 1, wherein a lower portion of the first electrode material layer is in direct contact with the third electrode material layer.

7. The semiconductor device of claim 1, wherein a distance between a lower surface of the lower electrode and a lower end of the second electrode material layer is about 0.4 to about 0.6 times a height of the lower electrode as measured between the lower surface of the lower electrode and an upper surface of the lower electrode.

8. The semiconductor device of claim 1, wherein the third electrode material layer comprises a lower portion having a first width, an intermediate portion on the lower portion and having a second width, and an upper portion on the intermediate portion and having a third width, and wherein the first width is greater than the second width and less than the third width.

9. The semiconductor device of claim 8, wherein the lower portion is in direct contact with the first electrode material layer, the intermediate portion is in direct contact with the second electrode material layer, and the upper portion is in direct contact with the first electrode material layer and the second electrode material layer.

10. The semiconductor device of claim 8, wherein a lower surface of the upper portion is in direct contact with an upper surface of the first electrode material layer and an upper end of the second electrode material layer.

11. The semiconductor device of claim 8, wherein a width of the intermediate portion decreases with distance from the lower portion.

12. The semiconductor device of claim 1, wherein the second electrode material layer has a cylindrical shape having open upper and lower ends.

13. The semiconductor device of claim 1, wherein a thickness of the second electrode material layer decreases with distance toward the bottom surface of the third electrode material layer.

14. A semiconductor device comprising:
a lower structure having a conductive region; and
an information storage structure electrically connected to the conductive region,
wherein the information storage structure comprises:
a lower electrode electrically connected to the conductive region, the lower electrode extending away from the lower structure in a first direction;
one or more support layers on a side surface of the lower electrode, the one or more support layers extending in a second direction that intersects the first direction;
a dielectric layer on the lower electrode and the one or more support layers; and
an upper electrode on the dielectric layer,
wherein the lower electrode comprises a first structure and a second structure on the first structure,
wherein the first structure comprises a first lower electrode layer and a third lower electrode layer, and
wherein the second structure comprises a first upper electrode layer that is continuous with the first lower electrode layer, a third upper electrode layer that is continuous with the third lower electrode layer, and an insertion layer between the first upper electrode layer and the third upper electrode layer.

15. The semiconductor device of claim 14, wherein the third upper electrode layer is in contact with an upper surface of the first upper electrode layer and a side surface of the insertion layer.

16. The semiconductor device of claim 14, wherein the one or more support layers comprises a lowermost support layer and an uppermost support layer, and
wherein an upper surface of the first upper electrode layer and an upper end of the insertion layer are lower than an upper surface of the uppermost support layer relative to the lower structure.

17. The semiconductor device of claim 16, wherein a lower end of the insertion layer overlaps the lowermost support layer in the second direction.

18. The semiconductor device of claim 16, wherein the upper end of the insertion layer is not coplanar with a lower surface of the uppermost support layer.

19. The semiconductor device of claim 16, wherein a portion of the first structure of the lower electrode is lower than a lower surface of the lowermost support layer relative to the lower structure, and
wherein a portion of the second structure of the lower electrode is higher than the lower surface of the uppermost support layer relative to the lower structure.

20. A semiconductor device comprising:
a lower structure having a conductive region; and
an information storage structure electrically connected to the conductive region,
wherein the information storage structure comprises:
a lower electrode electrically connected to the conductive region, the lower electrode extending away from the lower structure in a first direction;
one or more support layers on a side surface of the lower electrode, the one or more support layers extending in a second direction that intersects the first direction;
a dielectric layer on the lower electrode and the one or more support layers; and
an upper electrode on the dielectric layer,
wherein the lower electrode comprises a first electrode material layer having a cylindrical shape, a second electrode material layer on the first electrode material layer, and a third electrode material layer on the first electrode material layer and the second electrode material layer,
wherein the second electrode material layer is on an internal surface of an upper portion of the first electrode material layer, wherein the internal surface is within the cylindrical shape,
wherein the third electrode material layer comprises a lower portion, an intermediate portion, and an upper portion, and
wherein the lower portion of the third electrode material layer is surrounded by the first electrode material layer, the intermediate portion of the third electrode material layer is surrounded by the second electrode material layer, and the upper portion of the third electrode material layer is surrounded by one of the one or more support layers.
